(19) United States
(12) Patent Application Publication
(10) Pub. No.: US 2004/0130333 A1
(43) Pub. Date: Jul. 8, 2004

(54) Rf power measurement

(76) Inventor: Oliver James Hilton, Gloucestershire (GB)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(21) Appl. No.: 10/380,057

(22) PCT Filed: Oct. 2, 2001
(86) PCT No.: PCT/GB01/04378

(30) Foreign Application Priority Data
Oct. 4, 2000 (GB) 0024325.3

(51) Int. Cl. G01R 27/28

(52) U.S. Cl. 324/616

(57) ABSTRACT

A RF power measurement circuit for measuring RF power of a pulsed RF input signal has a sigma-delta ADC circuit and an AND gate for controlling delivery of clock pules to a clock input of the ADC circuit. The clock pulses are delivered to the clock input only within the duration of RF pulses of the pulsed RF input signal enabling a low speed ADC circuit to be used.

This invention relates to the measurement of RF power, and the invention relates particularly to a RF power measurement circuit and method employing an over-sampling analogue-to-digital conversion (ADC) circuit. As known to those skilled in the art, an over-sampling ADC requires a finite number N of clock cycles (where N>1) to complete a single conversion.

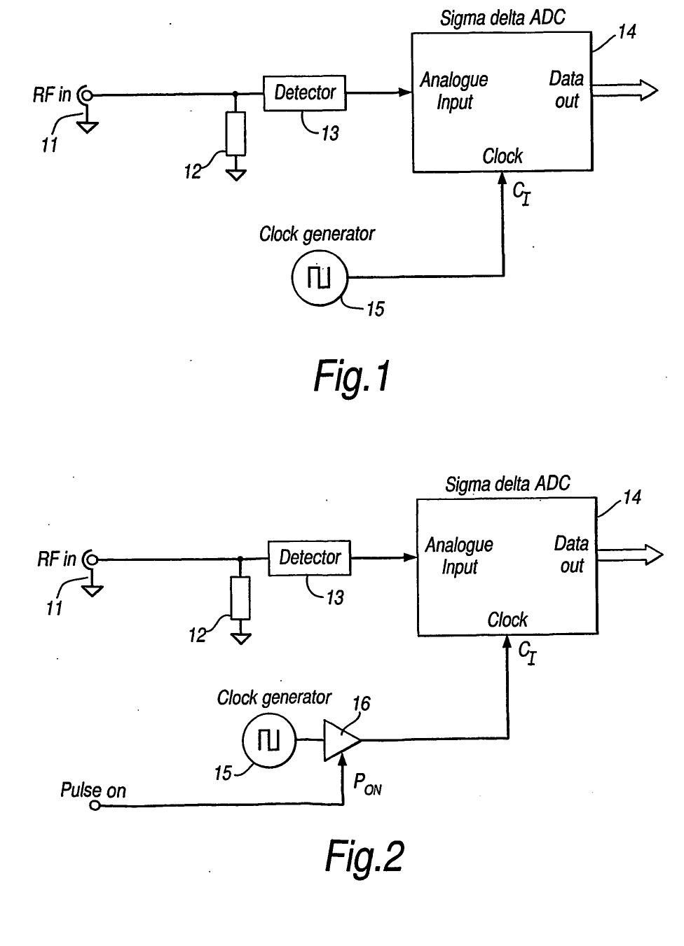

FIG. 1 of the accompanying drawings is a block diagram showing a known RF power measurement circuit. It comprises a RF input 11, a load 12, a Schottky diode 13, an over-sampling ADC circuit in the form of a sigma-delta ADC circuit 14 and a clock generator 15.

In use, Schottky diode 13 functions as a detector which outputs voltage related to RF power reaching the RF input 11. The ADC circuit 14 converts this voltage to digital format giving a measure of RF power which can be stored for further processing.

The clock generator 15 supplies clock pulses to the clock input C_{I} of the ADC circuit 14, and these pulses define the conversion rate of the ADC circuit. The conversion time T_{CONV} of the ADC circuit is given by the expression:

$${T}_{CONV} = \frac{N}{{F}_{CLOCK}} ,$$

where N is the number of clock pulses required to complete a single conversion and F_{CLOCK} is the frequency of the clock generator 15. Hitherto, it has been customary to use a high speed ADC circuit having a conversion time T_{CONV} which is much shorter than the RF pulse length, and so several power measurements can be derived from each RF pulse. Generally, a sigma-delta ADC circuit has been preferred since high ADC resolution can be realised at lower cost than other conversion techniques.

It would be desirable to use a low speed over-sampling ADC circuit which is significantly cheaper than a high speed over-sampling ADC circuit and yet is still capable of achieving high ADC resolution leading to improved measurement accuracy. However, a low speed over-sampling ADC circuit presents a significant technical problem when the conversion time of the ADC circuit is longer than the RF pulse length.

According to one aspect of the invention there is provided a RF power measurement circuit for measuring RF power of a pulsed RF input signal comprising detector means for converting said input signal to voltage, over-sampling analogue-to-digital conversion means for deriving a measure of RF power from said voltage, clock generation means for generating clock pulses and means for controlling delivery of said clock pulses to a clock input of said over-sampling analogue-to-digital conversion means.

In a preferred implementation, said means for controlling causes said clock pulses to be delivered to said clock input only within the duration of RF pulses of the pulsed RF input signal and, preferably, after the start of respective RF pulses. Since, with this arrangement, clock signals are delivered to the clock input of the ADC only within the duration of the RF pulses, it is possible to derive a single power measurement from two or more successive RF pulses. Accordingly, this arrangement enables use of a low speed over-sampling ADC having a conversion time longer than the RF pulse length.

According to another aspect of the invention there is provided a method of measuring RF power of a pulsed RF signal comprising the steps of converting the pulsed RF signal to voltage, using over-sampling analogue-to-digital conversion means to derive a measure of RF power from said voltage and controlling delivery of clock pulses to a clock input of said over-sampling analogue-to-digital conversion means.

An embodiment of the invention is now described, by way of example only, with reference to the accompanying drawings of which:

FIG. 1 is a block diagram showing a known RF power measurement circuit,

FIG. 2 is a block diagram showing a RF power measurement circuit according to the invention, and

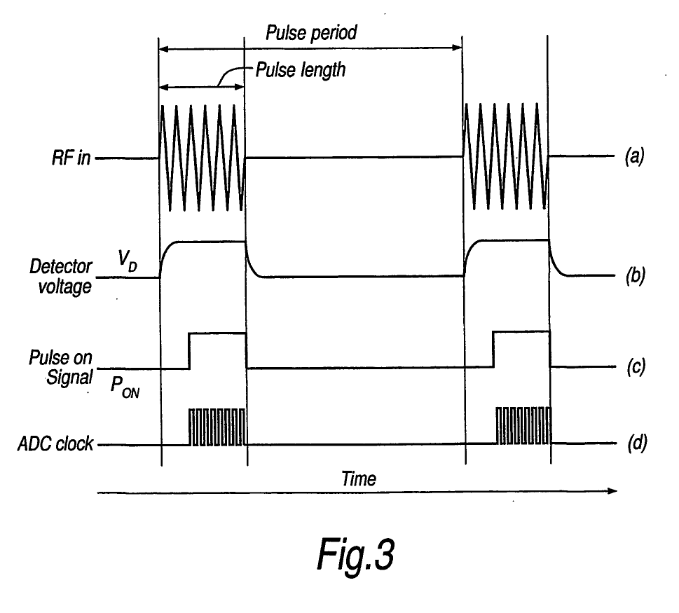

FIGS. 3(a) to 3(d) are timing diagrams useful in understanding operation of the RF power measurement circuit shown in FIG. 2.

Referring to FIG. 2, many of the circuit components are the same as those used in the circuit of FIG. 1, and have been ascribed like reference numerals.

As in the case of the circuit shown in FIG. 1, a RF input signal R_{IN} (shown in FIG. 3(a)) is received at the RF input 11, terminated by the load 12 and converted by Schottky diode 13 to voltage V_{D} (shown in FIG. 3(b)) related to RF power reaching the RF input 11. The sigma-delta ADC circuit 14 then converts the detected voltage V_{D} to digital format and thereby generates data representing a measure of RF power at the converter output.

As before, the RF power measurement circuit 14 has a clock generator 15, but differs from the circuit of FIG. 1 by provision of AND gate 16 connected between the clock generator 15 and the clock input C_{I} of the ADC circuit 14. The AND gate 16 has an output terminal connected to the clock input, a first input terminal connected to the clock generator 15 and a second input terminal connected to receive an externally generated ‘Pulse-on’ signal P_{ON} in the form of a pulse train (shown in FIG. 3(c)). The AND gate 16 functions, in effect, as a switch enabling clock pulses to be delivered to the clock input C_{I} of the ADC circuit 14 while the switch is closed (when P_{ON} is “high”) and preventing such delivery when the switch is open (when P_{ON} is “low”). The timing of the ‘Pulse-on’ signal is related to the timing of the RF pulses of the RF input signal and its effect is to enable delivery of clock pulses to the clock input C_{I} of the ADC circuit 14, but only within the duration of the RF pulses (as shown in FIG. 3(d)). Thus, pulses will only be delivered to the clock input when a RF pulse is present.

As shown in FIG. 3(b), Schottky diode 13 has a significant time constant causing the detection voltage V_{D} to rise and fall exponentially in response to leading and trailing edges respectively of each RF pulse. To take account of this, each pulse of the ‘Pulse-on’ signal P_{ON} is generated a short time after the start of the associated RF pulse thereby allowing the detector voltage sufficient time to settle before any clock pulses are delivered to the clock input of the ADC circuit. In practice, to enable accurate power measurements to be made, the detector time constant should be much shorter than the RF pulse length.

Since the clock signals are delivered to the clock input of the ADC circuit 14 only within the duration of the RF pulses, it is possible to derive a single power measurement from two or more successive RF pulses; accordingly, a low speed ADC circuit can be used, having a conversion time which is much longer than the RF pulse length.

Alternatively, a high speed ADC circuit could be used; in this case, the timing of the ‘Pulse-on’ signal P_{ON} will eliminate power measurements that would otherwise be made while the detector voltage V_{D} is rising or falling, thereby improving accuracy of the measurement.

It will be appreciated that although the RF power measurement circuit described with reference to FIG. 2 includes a sigma-delta ADC circuit, other forms of over-sampling ADC circuit could alternatively be used.

Similarly, although an AND gate 16 and a Schottky diode 13 have been used other components capable of performing substantially the same switching and detection functions could alternatively be used e.g. a synchronous clock enabling circuit could be used for the switching function and a field effect transistor could be used for the detection function.

It will also be appreciated that RF power may be measured over any desired part of the input waveform, which need not necessarily include a RF pulse.

1. A RF power measurement circuit for measuring RF power of a pulsed RF input signal comprising detector means for converting said input signal to voltage, an over-sampling analogue-to-digital conversion means for deriving a measure of RF power from said voltage, clock generation means for generating clock pulses and means for controlling delivery of said clock pulses to a clock input of said over-sampling analogue-to-digital conversion means.

2. A measurement circuit as claimed in claim 1 wherein said means for controlling is connected between said clock generation means and said clock input and is responsive to a control signal whose timing is related to the timing of RF pulses of the pulsed RF input signal.

3. A measurement circuit as claimed in claim 1 or claim 2 wherein said means for controlling causes said clock pulses to be delivered to said clock input only within the duration of RF pulses of the pulsed RF input signal.

4. A measurement circuit as claimed in claim 3 wherein said means for controlling causes said clock pulses to be delivered to said clock input after the start of respective said RF pulses.

5. A measurement circuit as claimed in claim 1 wherein said means for controlling comprises switching means responsive to control pulses.

6. A measurement circuit as claimed in claim 5 wherein the timing of said control pulses is related to the timing of RF pulses of said pulsed RF input signal.

7. A measurement circuit as claimed in claim 6 wherein the leading edge of each control pulse follows the start of a respective said RF pulse.

8. A measured circuit as claimed in any one of claims 5 to 7 wherein said switching means is an AND gate.

9. A measurement circuit as claimed in any one of claims 1 to 8 wherein said detection means is a Schottky diode.

10. A measurement circuit as claimed in any one of claims 1 to 9 wherein said over-sampling analogue-to-digital conversion circuit is a sigma-delta analogue-to-digital conversion circuit.

11. A measurement circuit as claimed in any one of claims 1 to 10 wherein said over-sampling analogue-to-digital conversion circuit has a conversion time longer than the RF pulse width.

12. A method of measuring RF power of a pulsed RF signal comprising the steps of converting the pulsed RF signal to voltage, using over-sampling analogue-to-digital conversion means to derive a measure of RF power from said voltage and controlling delivery of clock pulses to a clock input of said over-sampling analogue-to-digital conversion means.

13. A method as claimed in claim 12 wherein said controlling step causes said clock pulses to be supplied to said clock input only within the duration of RF pulses of the pulsed RF signal.

14. A method as claimed in claim 13 wherein said controlling step causes said clock pulse to be delivered to said clock input after the start of respective said RF pulses.

15. A RF power measurement circuit substantially as hereindescribed with reference to FIGS. 2 and 3 of the accompanying drawings.

16. A method of measuring RF power substantially as hereindescribed with reference to FIGS. 2 and 3 of the accompanying drawings.
